(19) United States
(12) Patent Application Publication
(10) Pub. No.: US 2014/0299169 A1
(43) Pub. Date: Oct. 9, 2014

(54) ELECTRONIC POWER MANAGEMENT SYSTEM FOR A WEARABLE THERMOELECTRIC GENERATOR

(71) Applicant: PERPETUA POWER SOURCE TECHNOLOGIES, INC., Corvallis, OR (US)

(72) Inventors: Leif E. Schneider, Albany, OR (US); Ingo Stark, Corvallis, OR (US); Marcus S. Ward, Salem, OR (US)

(73) Assignee: Perpetua Power Source Technologies, Inc., Corvallis, OR (US)

(21) Appl. No.: 13/859,729

(22) Filed: Apr. 9, 2013

(51) Int. Cl. H01L 35/02

(52) U.S. Cl. CPC H01L 35/02
USPC 136/201; 136/205

(57) ABSTRACT

A power management system for an energy harvesting device configured to provide a source voltage. The power management system may include a conditioning and control circuit configured to perform an initialization process by accumulating energy from the source voltage until an output voltage becomes regulated for a load. The power management system may include a priming circuit configured to supplement the source voltage during a load period upon actuation of a power management switch which may cause the transferring of a priming charge from a low-leakage energy storage element to the conditioning and control circuit. The conditioning and control circuit may combine the priming charge with the energy accumulating from the source voltage. The initialization process may cause the output voltage for the load to become regulated during the load period following actuation of the power management switch.

### FIELD

The present disclosure pertains generally to thermoelectric devices and, more particularly, to an electronic power management system for a wearable thermoelectric generator system or other energy harvesting device.

### BACKGROUND

The increasing trend toward miniaturization of microelectronic devices consuming less power has driven the development of miniaturized power supplies. Batteries are traditional power sources for such microelectronic devices. However, the power that is supplied by batteries dissipates over time requiring that the batteries be periodically replaced or recharged. Additionally, batteries may have a limited shelf life of months or years due to energy leakage, again requiring that they be replaced or recharged periodically. In order to avoid an excessive dependency on batteries, energy harvesting systems have been developed which convert sunlight, heat flow, electromagnetic energy, vibration, or pressure into electricity. For example, solar cells have an effectively unlimited useful life and may supply power to a microelectronics device without a dependency on batteries. Developments in electronics continue to decrease the power required to operate microelectronic devices, contributing to the feasibility of energy harvesting systems such as solar cells. Unfortunately, the power provided by solar cells may be transient when sunlight or light from other sources is not always available.

Thermoelectric generators may avoid the transient nature of solar power by converting a stable heat flow into electricity for powering a microelectronic device. When a thermoelectric generator is coupled to a heat source such as a hot pipe and to a heat sink, the thermoelectric generator may generate a source voltage that may vary in proportion to the temperature difference. For example, the temperature difference across a thermoelectric generator may typically range from approximately 5 K to approximately 100 K and may result in a proportional source voltage. The source voltage may be moderately low compared to a battery voltage. For example, the source voltage produced by a thermoelectric generator may be in the range of millivolts to several volts.

Since microelectronic devices powered by energy harvesters commonly require a fixed operating voltage in the range of 1.5V to 5.0V, the energy harvester system may require a conditioning circuit to boost and regulate the source voltage to produce an output voltage to be provided to a load such as a microelectronics device. Regulation of the output voltage may generally result in a sufficient and stable voltage level and current supply in order that the load may successfully complete its task over some period of time. The conditioning required to regulate an output voltage may depend on the magnitude and variability of the source voltage as well as the requirements of the microelectronics device. Unfortunately, the amount of power available from a thermoelectric energy harvesting system may fade prior to or during the performance of a task performed by the load such that the load (e.g., the microelectronic device) may be unable to perform or complete the task. Such a power fade may occur, for example, if a hot pipe supplying a heat flow to a thermoelectric generator becomes cool.

An additional challenge associated with energy harvesters is that the conditioning and control circuitry associated with a thermoelectric generator may require its own supply of power, placing an additional load demand on the energy harvester. For example, a conditioning and control circuitry may monitor voltage levels, record and store data, check battery charge levels, and execute switching or control functions, all of which may consume a portion of the harvested energy. In addition, boosting a source voltage to a higher output voltage required by a microelectronic device may require an initialization process that consumes energy. For example, conditioning circuitry may be charged up in the process of accumulating a higher and higher voltage potential from the source voltage, eventually reaching a normal operating mode and creating a regulated output voltage. During this initialization process, the operating efficiency of the boost converter may be much lower than in the normal operating mode. Therefore, it may be useful, in designing an energy harvesting system utilizing a boost converter, to minimize the number of times that an initialization process must occur. In conclusion, there may be multiple demands on the power available from a thermoelectric energy harvesting system, including the microelectronics device (load), the leakage from any storage elements such as batteries, the overhead power required to condition and control the system, and the initialization process.

Wearable thermoelectric generators are being developed which use the heat of a living body to supply power to microelectronic devices such as heart rate monitors, wireless transmitters, and other devices. Such wearable thermoelectric generators may be worn as a strap, a patch, a wrist band, or a pad against the skin, and may operate on a temperature differential resulting from heat produced by the body core, which may serve as a heat source, and the ambient environment, which may serve as a heat sink. Advantageously, the core of the human body maintains a relatively constant temperature, and therefore may be a reliable heat source. However, changes in skin temperature and ambient air temperature may cause a variation in the temperature difference across the thermoelectric generator, thereby causing the source voltage and the available power to vary substantially. Additionally, the muscle, fat, and skin that surrounds the body core may have a relatively high thermal resistance, limiting the heat flow available to a thermoelectric generator. In the case of a low rate of heat flow, a substantial amount of time may be required to initialize a wearable thermoelectric energy harvesting system. For example, a user (e.g., a wearer) may need to wait for several minutes or longer after donning the wearable thermoelectric generator before a sufficient amount of energy accumulates in the conditioning circuit to power a load (i.e., a microelectronic device).

Heat flow through a thermoelectric generator may be increased by matching the thermal resistance of the thermoelectric generator to the thermal resistance of the body. Thermal matching may result in the maximization of the power output, similar to the maximum power transfer that occurs as a result of electrical matching (e.g., impedance matching) a power source to a load in an electrical circuit. For example, an in-plane thermoelectric generator may provide a better thermal match with the body relative to the thermal match than is available with a cross-plane thermoelectric generator. Nevertheless, because of a relatively low temperature difference across a wearable thermoelectric generator and because of the high thermal resistance of body tissue, the typical source voltage of an in-plane wearable thermoelectric generator may require an intelligent and frugal use of the energy that is harvested so that a microelectronics device can be reliably powered.

One solution to the above-noted limits associated with powering a load with a wearable thermoelectric generator may be to turn on the microelectronics device or load only when needed. For example, in the case of a radio frequency identification (RFID) device, power may be momentarily provided to the RFID device to enable a burst radio transmission. The power to the RFID device may then be shut off to allow for the storing up of energy generated by the thermoelectric generator for the next load event. In this regard, it may be desirable to shut off power to part or all of the entire energy harvesting system in certain circumstances as a means to eliminate overhead power drain associated with conditioning and control circuitry that may be coupled to the wearable thermoelectric generator.

Another solution to the above-noted limits associated with powering a load with a wearable thermoelectric generator may be to use a rechargeable battery to power the microelectronic load when source voltage is anemic. Unfortunately, a rechargeable battery may require recharging during times of high output voltage from the thermoelectric generator. If the wearable thermoelectric generator rarely experiences high output, the rechargeable battery will gradually lose charge over time and may eventually require external charging or replacement.

As can be seen, there exists a need in the art for an ultra low power management system to frugally and intelligently manage harvested thermoelectric energy in order to reliably power a microelectronics load. More specifically, there exists a need in the art for a power management system capable of quickly generating a usable and regulated output voltage in response to a demand for power, particularly over a boost circuit initialization process or for the duration of a load event. Additionally, there exists a need in the art for a power management system capable of anticipating future demands for power so that energy needs can be prioritized, energy resources conserved, and fades in output power may be prevented. Furthermore, there exists a need in the art for energy storage elements of modest capacity and that do not leak over time so that a minimum of harvested energy is required to maintain a charge on the storage element. There is also a need in the art for energy storage elements that can be charged over a wide range of voltages in order to take advantage of the smaller and variable source voltages that may be available from a wearable thermoelectric generator.

### SUMMARY

The above-noted needs associated with power management systems for wearable thermoelectric generators are specifically addressed and alleviated by the present disclosure in which, in an embodiment, a power management system may be provided for a thermoelectric generator or other energy harvesting device. The power management system may be configured to be coupled to the energy harvesting device. The power management system may include a conditioning and control circuit configured to perform an initialization process by accumulating energy from a source voltage until an output voltage becomes regulated for a load. The power management system may include a priming circuit configured to supplement the source voltage during a load period upon actuation of a power management switch. The actuation of the power management switch may cause the transferring of a priming charge from a low-leakage energy storage element to the conditioning and control circuit. The conditioning and control circuit may combine the priming charge with the energy accumulating from the source voltage. The initialization process may cause the output voltage for the load to become regulated during the load period following actuation of the power management switch.

In another embodiment, provided is a power management system for a wearable thermoelectric generator. The thermoelectric generator may be configured to be thermally coupled to a living body and provide a source voltage that varies according to a temperature difference across the thermoelectric generator. The power management system may include a conditioning and control circuit configured to perform an initialization process by accumulating energy from the source voltage until an output voltage becomes regulated for a load. The power management system may include a priming circuit configured to supplement the source voltage during a load period upon actuation of a power management switch. The priming circuit may further include a low-leakage energy storage element, a temporary storage element, a timing circuit, and a transistor switch.

The transistor switch may have a first and a second pass terminal and a pass channel therebetween which is normally open. The power management switch may couple to the gating terminals of the transistor switch through the timing circuit. The low-leakage energy storage element may connect to the first pass terminal, and the temporary storage element may connect to the second pass terminal. A charging current may cease according to the timing circuit following the actuation of the power management switch, whereupon the temporary storage element may be charged with a priming charge substantially less than a storage capacity of the low-leakage energy storage element. The temporary storage element may be connected to the conditioning and control circuit where the priming charge combines with the energy accumulating from the source voltage. The initialization process may cause the output voltage for the load to become regulated during the load period following actuation of the power management switch.

Also disclosed herein is a method of increasing the power available to a load in a of an energy harvesting device such as a wearable thermoelectric energy harvesting system. The method may include delivering a source voltage from a wearable thermoelectric generator to a conditioning and control circuit and to a load. The method may further include accumulating, within the conditioning and control circuit, energy from the source voltage until an initialization process results in an output voltage being regulated for the load. The method may additionally include detecting an amount of power available to the load during a load period being less than a predetermined threshold. The method may further include actuating a power management switch causing the transferring of a priming charge from a low-leakage energy storage element to a temporary storage element and presenting the priming charge to the conditioning and control circuit. The method may also include combining the priming charge with the energy accumulating from the source voltage, thereby regulating the output voltage for the load during the load period. The method may further include maintaining a regulated output voltage during subsequent load periods by harvesting power from the thermoelectric generator, wherein the priming charge is substantially less than a capacity of the low-leakage energy storage element.

The features, functions and advantages that have been discussed can be achieved independently in various embodiments of the present disclosure or may be combined in yet other embodiments, further details of which can be seen with reference to the following description and drawings below.

### BRIEF DESCRIPTION OF THE DRAWINGS

These and other features of the present disclosure will become more apparent upon reference to the drawings wherein like numbers refer to like parts throughout and wherein:

FIG. 1 is a schematic diagram of a thermoelectric energy harvesting system including a power management system;

FIG. 2 is a block diagram of a thermoelectric energy harvesting system including a power management system;

FIG. 3 is an illustration of a wearable thermoelectric energy harvesting system having at least one thermoelectric generator and shown being worn as an armband on an arm of a person; and

FIG. 4 is a cross sectional view of the system taken along line 4 of FIG. 3.

### DETAILED DESCRIPTION

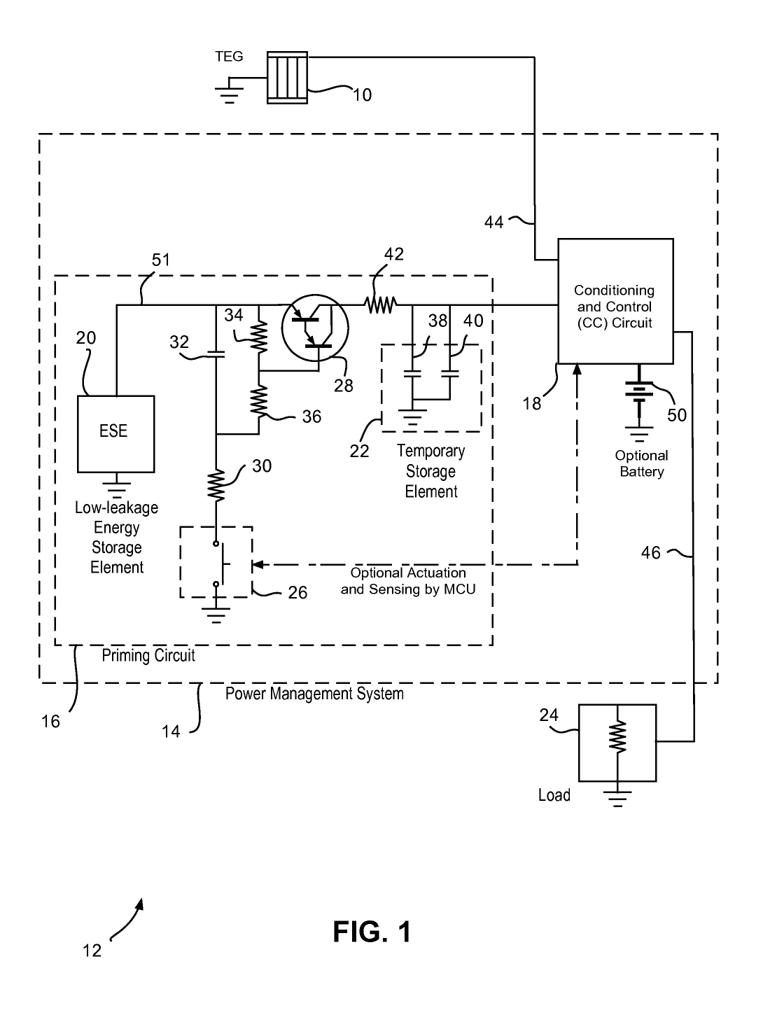

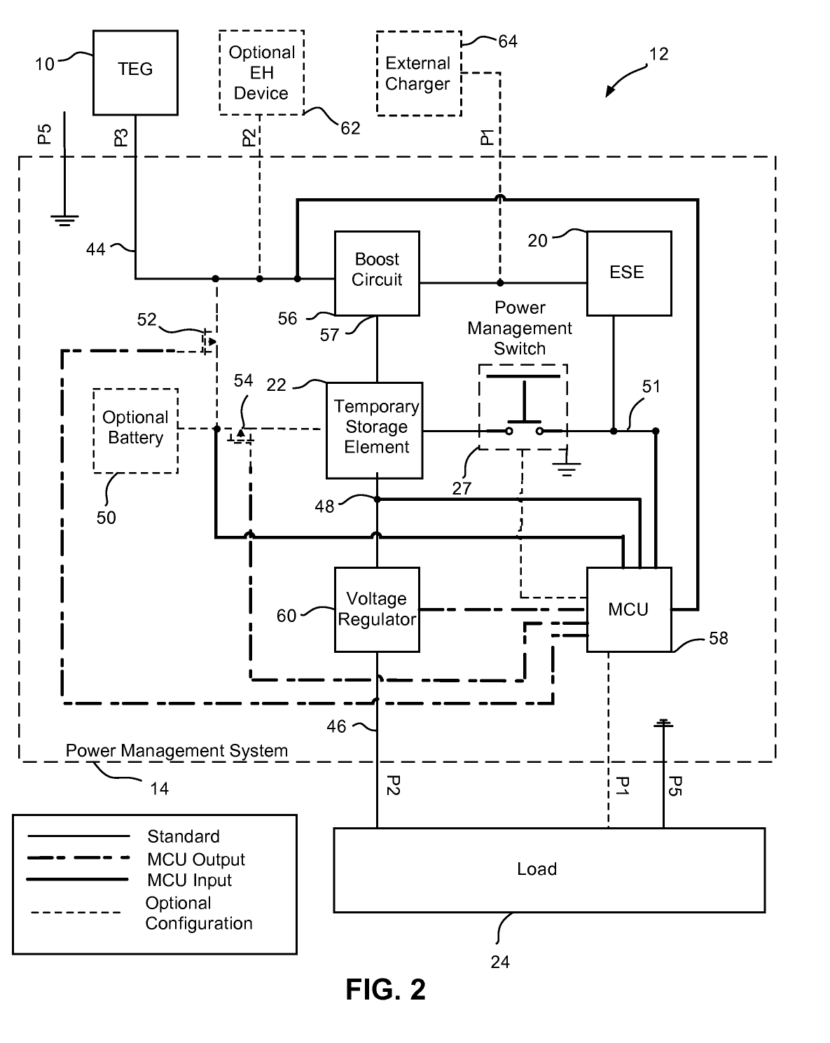

Referring now to the drawings wherein the showings are for purposes of illustrating various aspects of the present disclosure, shown in FIG. 1 is a schematic of an embodiment of a thermoelectric energy harvesting system 12 wherein one or more thermoelectric generators (TEGs) 10 may deliver a source voltage 44 to a conditioning and control (CC) circuit 18 which then provides an output voltage 46 to load 24. The thermoelectric generators 10 may be connected in series and/or in parallel. The source voltage 44 refers to a generated voltage of an energy harvesting device (e.g., a thermoelectric generator) which results in an electrical current to the power management system resulting in power delivered to the load 24. Load 24 may comprise an microelectronics device. Conditioning and control circuit (CC circuit) 18 may comprise several blocks described in an embodiment in FIG. 2 below, including a microcontroller (MCU) 58 for monitoring and control, a boost circuit 56 for providing an output voltage 46 higher than source voltage 44, and optionally a voltage regulation circuit 60 such as a low drop out voltage regulator or a buck converter, (e.g., the buck converter TPS62736 from Texas Instruments™). For example, a boost circuit such as the BQ25504 from Texas Instruments™ may be used and which is designed to start up if there is at least 330 mV at the input (source voltage 44) and designed to keep operating as long as the input remains above 80 mV. Also, the boost circuit may be placed in standby or sleep mode to conserve power. Alternately, in the case of a high source voltage, the boost circuit may be eliminated and bypassed so that the source power may be passively conditioned and passed through to the load 24.

Referring still to FIG. 1, the conditioning and control circuit 18 may provide conditioning of source voltage 44 in order to provide for a regulated output voltage 46. The conditioning required to provide for a regulated output voltage 46 may depend on the magnitude and variability of the source voltage 44 as well as on the requirements of the microelectronics device, and may include a boost circuit, a buck circuit, filtering, voltage limiting, voltage regulation, current regulation, energy storage, impedance matching, fusing, and other kinds of signal conditioning. For example, a kind of conditioning that may occur in place of a conventional boost circuit may include a natural voltage pass through with minimal processing.

In an embodiment, boost voltage converters like the BQ25504 accumulate charge from the input (e.g. source voltage 44) and step up the output voltage 46 to a regulated level. Once a thermoelectric generator (TEG) 10 has begun to produce a source voltage 44 in excess of the start up threshold of the boost converter 56, an initialization process may occur, and may eventually result in a sufficient and stable voltage level and current supply in order that the load 24 (e.g. microelectronics device) may begin and successfully complete its task. Once initialization has occurred, the boost converter 56 may continue to provide a stable output voltage 46 as long as the power received from the thermoelectric generator 10 is somewhat larger in an amount sufficient to overcome conversion efficiencies. For example, a typical boost circuit may normally operate at an efficiency of 75-95%, and may operate at an efficiency of 10-30% during initialization. However, if the power delivered by the thermoelectric generator 10 decreases and once again becomes inadequate, the output voltage 46 may fall out of regulation (i.e., fade), which may then require another initialization process in order to reestablish normal operation. Unfortunately, the initialization process occurs at a low operating efficiency, thereby consuming a much greater portion of the harvested power than occurs for regulated output voltages.

Referring still to FIG. 1, in an embodiment, optional battery 50 may be used to supplement the demands of the load 24 and of the internal circuitry of CC circuit 18. Optional battery 50 may be a rechargeable battery or a non-rechargeable battery. Control circuitry internal to the CC circuit 18 may provide sensing, switching, charging, and control functions to route the flow of current out of the battery 50 during discharge and into the battery 50 during charge. If there is no battery 50 and there is a fade in power delivered by thermoelectric generator 10, power to the load 24 may cease or become degraded unless additional input power can be found. Alternately, load 24 may be configured to operate periodically for a short load period, perhaps transmitting a burst of data. In such a case, the load 24 may be switched off by the CC circuit 18, conserving power for charging a battery 50 or other storage elements. In another scenario, power generated by a wearable thermoelectric generator 10 may be continuously routed to the load 24, whether or not the power is sufficient to complete a load event lasting for some time period, and then used periodically at the discretion of the load 24, if power is available. In this case, a user may have occasion to utilize the load and find the load unresponsive. For example, the user may wish to transmit a signal or record a biological reading and not be able to do so because there is inadequate source voltage 44 at the input of the CC circuit 18.

Power management system 14 comprises conditioning and control circuit (CC circuit) 18 and priming circuit 16, and provides for a number of intelligent power management options as described below and illustrated in the description for FIG. 2. Power management switch 26 may be actuated by a user, causing the transfer of a priming charge (not shown) from a low-leakage energy storage element (ESE) 20 to temporary storage element 22. For example, low-leakage storage element 20 may comprise a thin film lithium-ion rechargeable battery. Temporary storage element 22 may then present its charge to CC circuit 18 where shortages in the energy accumulating from source voltage 44 may be supplemented by the priming charge according to the operation of a voltage converter circuit within CC circuit 18. For example, a voltage converter within CC circuit 18 may be a boost converter, a buck converter, or a low drop out voltage regulator. The energy of the priming charge may be sized to substantially support only one successful load event during a load period, whereafter thermoelectric generator 10 energy may be sufficient to power subsequent load activity. Alternatively, the priming charge may be chosen to support a load period of different duration as anticipated by various measurements, data, and objectives known within CC circuit 18. For example, a stored history of past source voltage 44 and projected load demand may suggest a priming charge that may be sized to support successful operation of the load during a load period of time. In an embodiment, power management switch 26 may be a momentary switch which may temporarily ground one end of timing capacitor 32 through switch resistor 30, thereby turning on transistor switch 28 for a period of time set by timing resistors 34 and 36 and timing capacitor 32.

In another embodiment, shortages in the energy accumulating from source voltage 44 may be supplemented by the priming charge according to the operation of conditioning circuitry within CC circuit 18 which is other than a boost converter, a buck converter, or a low drop out voltage regulator. For example, a pass through circuit may provide an elegant solution to power management when source voltage 44 and temperature differentials are moderate to high, such as when source voltage 44 is regularly greater than approximately 1 volt. A conditioning circuit within CC circuit 18 may employ filtering, impedance matching, current limiting, energy storage, or other kinds of signal conditioning appropriate to establishing an adequate and stable output voltage for a load 24. Temporary storage element 22 may then present its priming charge to CC circuit 18 where shortages in the energy accumulating from source voltage 44 may be supplemented by the priming charge and may thereby establish an output voltage 46 which is regulated for a load 24.

Referring still to FIG. 1, capacitors 38 and 40 may form a temporary storage element for holding the priming charge dispensed from low-leakage energy storage element 20 while CC circuit 18 utilizes the energy of the charge. Advantageously, the transfer of the priming charge to temporary storage element 22 may occur over a period of time that may be substantially shorter than the load period over which a regulated output voltage 46 may benefit from the priming charge, and may thereby reduce losses occurring in priming circuit 16 and in low-leakage energy storage element (ESE) 20. Charging resistor 42 limits a rate of current flow into capacitors 38 and 40. Transistor switch 28 may be a high-current-gain transistor in order to minimize circuit losses. In an embodiment, transistor switch 28 is a Darlington transistor. The use of a high-current-gain transistor for transistor switch 28 and the use of a relatively short transfer time may isolate ESE 20 and ESE storage voltage 51 from the rest of the circuit, thus carefully preserving its charge. For example, low-leakage energy storage element (ESE) 20 may be a thin film lithium-ion rechargeable battery such as the THINERGY® Micro-Energy Cell from Infinitive Power Solutions, or the EnerChip™ from Cymbet, or the EnFilm™ from STMicroelectronics. For example, an ESE may only leak out 1% of its stored charge over one year. Other ESE product may have higher or lower rates of leakage.

A low-leakage energy storage element (ESE) used for storage element 20 may have a moderate storage capacity that is substantially in between the high storage capacity of a small battery, such as a button or coin cell, and the low storage capacity of a large capacitor. In this manner, a priming circuit 16 may elegantly solve the unique challenges of a wearable thermoelectric energy harvesting system by utilizing the correctly-sized components for their respective best purposes. For example, in an embodiment, an ESE may have a capacity of approximately 1 Joule at 4 volts compared to a battery having a capacity of approximately 2 orders of magnitude larger than that of an ESE. By comparison, temporary storage element 22 may have a capacity that is approximately 2 orders of magnitude smaller than that of an ESE. For example, a temporary storage element sized at 1200 g may have a capacity of approximately 0.01 Joules at 4 volts.

In an embodiment, capacitors 38 and 40 may comprise tantalum capacitors, chosen for their low internal losses. The ratio of the capacity of storage element 20 to the capacity of storage element 22 may be on the order of 100, in an embodiment, meaning approximately 100 priming charges may be transferred before storage element 20 must be recharged. Alternatively, other ratios of storage capacity may be chosen depending on the frequency and severity of outages anticipated for a particular energy harvesting scenario. By choosing design values for storage elements 20 and 22, and by proper load 24 and thermoelectric generator 10 sizing, a frugal and intelligent compensation for weak or variable source voltage 44 may be achieved without the use of conventional batteries.

In an embodiment, FIG. 1 shows an ESE being used for low-leakage storage element 20. Ideally, an ESE is a passive device and may be charged at any voltage potential within its rated specifications, unlike a conventional battery which has a charging threshold that the charging voltage must be greater than. Alternatively, the ESE 20 may be a small battery having a charging threshold. Therefore, various charging arrangements may be envisioned and are described in FIG. 2 below. A charging voltage for the low-leakage energy storage element 20 may by applied from source voltage 44 or from other intermediate voltages available within power management system 14, or from an external charger 64 (FIG. 2), such as a USB charger or wall-outlet charger. Various switching arrangements may be possible, as described in FIG. 2 below.

Referring to the embodiments of FIG. 1 and FIG. 2, power management switch 26 may alternatively be actuated by a microcontroller within CC circuit 18 instead of the demand to power a microelectronics device being actuated by a user pushing a power management switch 26. Various metrics may be used by the microcontroller (MCU) 58 (shown in FIG. 2) to detect or anticipate low or unstable output voltage 46 across a load over a load period, and a predetermined threshold set to actuate a priming charge through power management switch 26. Metrics that may be inform the actuation of a priming charge may include source voltage 44, the occurrence of a boost circuit initialization process, buck converter status, output voltage 46, low voltage on an energy storage element, current flow to load 24, voltage regulator status, load schedules, load outage reports, air temperature, body temperature, and other measures of system health that might indicate or anticipate that the microelectronics load may be inoperative over a load period. The microcontroller (MCU) 58 may generate an interrupt signal which may be used to indicate that there is sufficient power available for the load as represented by the electrical connection arrangement designated as P1 in FIG. 2.

Alternatively, in another embodiment, the user may be given the option of toggling between turning off the energy harvesting system in order to conserve power or actuating a priming charge, both options being initiated by actuating the power management switch 26. For example, in the case of an on/off push button, power management switch 26 may be a toggle switch. Such a toggle switch may be a single-pole-double-throw switch whereas a momentary push button may be a single-pole-single-throw switch. Other arrangements or their equivalents for switching for the purposes of priming and conserving power are disclosed herein. For example, the power management switch 26 may not directly activate priming circuit 16, but may instead inform the microcontroller (MCU) 58 of a desire for a priming charge wherein the MCU 58 then controls the routing of a parcel of energy from a low-leakage energy storage element 20 to the conditioning and control circuit 18 for the purposes of either establishing a regulated output voltage 46 in the current load period or ensuring a regulated output voltage 46 in a future load period.

Referring now to the block diagram of FIG. 2, in an embodiment, a thermoelectric energy harvesting system 12 may include one or more thermoelectric generators 10 that may deliver a source voltage 44 to power management system 14 which may provide an output voltage 46 to load 24. Boost circuit 56, microcontroller (MCU) 58, voltage regulator 60, and optional battery 50 may make up the conditioning and control circuit 18 (shown in FIG. 1). Boost circuit 56 processes source voltage 44, and may receive supplemental charge from temporary storage element 22 at a boost output terminal 57. During start up, boost circuit 56 may accumulate charge from thermoelectric generator 10 in order to establish a regulated and normal operating point suitable for stable powering of load 24. MCU 58 may sense the source voltage 44 as a measure of system health and in order to decide how to optimize the operating point of the thermoelectric energy harvesting system.

Thermoelectric generator 10 may include a bridge rectifier (not shown) to allow for reversing the polarity of source voltage 44 in the event that there is a reverse in the temperature gradient across thermoelectric generator 10. Upon the occurrence reversal in the temperature gradient, the bridge rectifier (not shown) will ensure that a positive source voltage 44 is still delivered to power management system 14. Additionally, thermoelectric generator 10 may include a reverse polarity protection circuit (not shown) in order to protect the thermoelectric generator 10 if there is a polarity shift.

Referring still to FIG. 2, in an embodiment, priming circuit 16 (FIG. 1) may consist of power management switch 27 (FIG. 2) connecting to low-leakage energy storage element (ESE) 20 (FIG. 2) and to temporary storage element 22 (FIG. 2). Power management switch 27 may contain the push button switch 26 of FIG. 1 plus the resistor-capacitor timing circuit and transistor switch 28 of FIG. 1. When power management switch 27 is actuated, a portion of the charge stored ESE 20 may be transferred to temporary storage element 22 in order to supplement the power derived from thermoelectric generator 10 so that a sufficient and stable output power may result in output voltage 46. A priming charge from temporary storage element 22 may connect to boost output terminal 57 and combine with the energy accumulating from source voltage 44 within boost circuit 56 in order to assist in the completion of an initialization process, or in order to prevent the output voltage 46 from fading to a low or unstable level.

Using a variety of metrics collectable or programmed, the microcontroller (MCU) 58 may actuate power management switch 27 in order to assure a sufficient and stable voltage level and current supply so that load 24 may successfully complete its task. The MCU 58 may control FET switches 52 and 54 to cause optional battery 50 to supplement source voltage 44, or to cause temporary storage element 22 to supplement source voltage 44, or to cause optional battery 50 to charge up temporary storage element 22. In this way redundancy or flexibility may be achieved in power management system 14. MCU 58 may also disable, enable, or adjust voltage regulator 60 to conserve harvested power or to regulate output voltage 46 as necessary. Voltage regulator 60 may comprise a low drop out voltage regulator or a buck converter circuit. MCU 58 may sense the voltage of optional battery 50, temporary storage voltage 48, ESE voltage 51, and/or source voltage 44 for the purpose of make control decisions regarding operating point, load shedding, and actuating a priming sequence. MCU 58 may optionally receive supply power from optional battery 50, from temporary storage element 22, or from thermoelectric generator 10. MCU 58 may sense the manual actuation of power management switch 27 in order to log behavior, such as logging energy harvesting history. MCU 58 may also sense power management switch 27 state changes that may be actuated manually by a user in order to deactivate the boost converter 56 and/or other power-consumptive stages.

Referring still to FIG. 2, in an embodiment, an optional energy harvesting source 62, such as another thermoelectric generator, solar, vibration device such as piezoelectric device, or electromagnetic generator, may be connected to the power management system 14 in order to supplement the thermoelectric energy harvesting system 12, or in order to provide a primary source of power. External charger 64 may be plugged into power management system 14 in order to supply power to load 24, to charge low-leakage energy storage element 20, or to operate the power management system 14. Optionally (not shown), thermoelectric generator 10 may be connected directly to load 24 and to MCU 58. Advantageously, the optional means of connecting a high capacity battery, a medium capacity energy storage element, and/or a low-capacity tantalum capacitor to a power management system 14, and to optionally make a direct bypass connection of thermoelectric generator 10 to load 24, as well as to allow an exchange of energies between these various system elements, facilitates or enables a balancing of the input and output of energy in the wearable thermoelectric energy harvesting system 12.

Although the above descriptions refer largely to wearable thermoelectric energy harvesting systems, it is to be understood that non-wearable thermoelectric energy harvesting systems as well as non-thermoelectric energy harvesters may benefit from the disclosed power management system without limitation.

The following is a description of the mechanical and thermal characteristics of a wearable thermoelectric energy harvesting system, as well as descriptions of the microelectronic devices that may be supportable by the energy harvesting system.

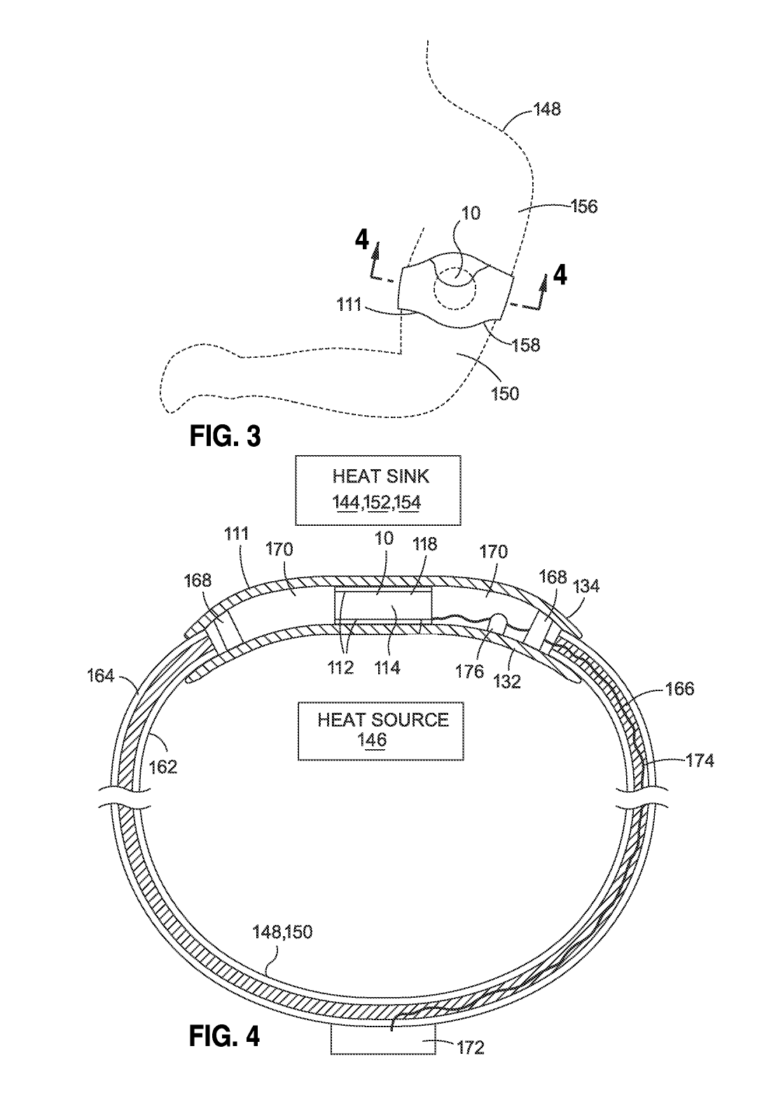

Shown in FIG. 3 is an embodiment of a wearable thermoelectric generator system 111 having one or more thermoelectric generators 10 and including one or more features and/or means for optimizing the matching of the thermal resistance of the thermoelectric generator 10 with the thermal resistance of an environment 144 to which the thermoelectric generator 10 may be exposed. The load may comprise a device such as an electronics module or other device that may be packaged separately from the thermoelectric generator 10 and/or the system 111. The load may comprise any device, without limitation, that may be powered by the system 111 such as a sensor such as a body function sensor, an environmental sensor, a rechargeable battery, a light, a portable communication device such as a cellular telephone, a portable audio player such as a digital audio player, or any other type of device, without limitation.

The one or more thermoelectric generators 10 that may be included with the system 111 may be provided in any configuration including, but not limited to, an in-plane configuration and/or a cross-plane configuration. Advantageously, an in-plane thermoelectric generator 10 is highly complementary for use in wearable applications such as in the wearable thermoelectric generator system 111 disclosed herein due to the relative ease of adjusting the thermal resistance of an in-plane thermoelectric generator 10 by making geometry adjustments. For example, the thermal resistance of an in-plane thermoelectric generator 10 may be adjusted by adjusting the geometry (i.e., length, width, thickness, etc.) of the n-type and p-type semiconductor legs of the in-plane thermoelectric generator 10 to obtain optimal thermal matching between the a living body and the thermoelectric generator 10. Advantageously, the use of an in-plane geometry may compensate for the lower temperature gradient that may be encountered in a wearable application of thermoelectric generators 10.

Although FIG. 3 illustrates the wearable thermoelectric generator system 111 in an open or closed band configuration such as an armband 158 mounted to a wearer's arm 156 and dissipating heat to air 154, the system 111 may be provided in any one of a variety of alternative configurations. For example, the system 111 may also be provided as a leg band, a head band, a foot band, an article of clothing, a patch, an appliqué, a layer, a strip, an article configured to be carried or held, or any one of a variety of other configurations for exploiting body heat of a user wearing the system 111. The system 111 may also be implemented for use in a structural article, a nonstructural article, a system, a subsystem, an apparatus, an assembly, a vehicle, a building, an inanimate object, and any one of a variety of other implementations, without limitation. The system 111 may also be used with or on a living body such as with animals (e.g., non-human), such as in livestock for powering RFID sensors for tracing locations of livestock, and/or for monitoring one or more physiological parameters of livestock. In this regard, the heat source 146 may comprise a body of a human, a body of an animal, or any other type of heat source. The heat sink 152 may comprise ambient air, a fluid including a gas or a liquid of any composition, solid matter of any composition, or any other type of heat sink.

Although not shown, the wearable thermoelectric generator system 111 may provide power for any one of a variety of applications. Non-limiting examples of applications where the system 111 may be implemented to provide power include wireless sensor systems, wireless sensor nodes, ultra-low power radio-transmitters, wireless Body Area Network (WBAN). The system 111 may also be configured to provide power for charging energy storage devices such as rechargeable batteries. In addition, the system 111 may be configured to provide power to sensors and actuators. For example, the system 111 may provide power to sensor for measuring temperature, blood pressure, hearing, breathing, vision, pulse, oxygen saturation, glucose level, electrocardiography (ECG), electroencephalography (EEG), chemical sensors for measuring toxins, such as carbon monoxide, and also for implants. The system 111 may also be implemented to power accelerometers for measuring movement, sensors for sensing position, and other measurements.

Referring to FIG. 4, shown is a cross section of an embodiment of the wearable thermoelectric generator system 111. The system 111 may include a highly thermally conductive heat collector 132 that may be configured to interface with or be placed in contact with a heat source 146 such as the skin surface 150 of the body 148 of a wearer. When the ambient air is at room temperature (e.g., approximately 68° F. to 72°), the skin surface 150 of the wearer may be at a temperature of approximately 68° F. to 98° F. The system 111 may also be configured to operate when mounted over a layer of material such as fabric or other material covering the wearer's skin in order to prevent a reduction in the temperature of the wearer's skin and maintain heat flow through the thermoelectric generator 10. In this manner, the system 111 may be configured to produce a high level of power by mounting over a covered body 148 part.

Referring still to FIG. 4, the system 111 may include at least one thermoelectric generator 10 although the system 111 may include multiple thermoelectric generators 10 that may be mounted to the system 111 in spaced relation to one another in order to reduce the thermal path from the heat source 146 (e.g., the wearer's body) to the heat exchanger 134 as described in greater detail below. In FIG. 4, the thermoelectric generator 10 is shown in an embodiment wherein the thermoelectric generator 10 includes heat couple plates 112 that may be placed between the heat collector 132 and the heat exchanger 134. However, the system 111 may be configured in an embodiment wherein a core 118 of the thermoelectric generator 10 may be placed directly between the heat collector 132 and the heat exchanger 134 and the thermoelectric generator 10 may be provided without heat couple plates 112. The core 118 may comprise the substrate 114 material and a plurality of thermocouples disposed on the substrate 114. The heat collector 132 and/or the heat exchanger 134 may extend at least across a width of the core 118 and may be mounted directly to the core 118 of the thermoelectric generator 10.

Referring to FIG. 4, the inner and outer material layer 162, 164 may be attached to the heat collector 132 and/or heat exchanger 134 such as by bonding and/or mechanically fastening the inner and outer material layer 162, 164 between the heat collector 132 and heat exchanger 134 or attaching to the outer surfaces of the heat collector 132 and heat exchanger 134. Spacers 168 made from polymeric material may be included at the terminal ends of the inner and outer material layer 162, 164 at the attachment point to the heat collector 132 and heat exchanger 134. An insulation layer 170 may be installed in the region between heat collector 132 and heat exchanger 134 on one side or both sides of the thermoelectric generator 10. The insulation layer 170 may fill at least partially fill a gap between the sides of the thermoelectric generator 10 and the ends of the inner and outer material layer 162, 164 at the attachment thereof to the heat collector 132 and/or the heat exchanger 134.

Referring to FIG. 4, the wearable thermoelectric generator system 111 may include an electronics 172 box or compartment or assembly. The electronics 172 may comprise the power management system 10 described above for the one or more thermoelectric generators 10. The electronics 172 may also include the final electronics such as a sensor, a charging system, or other final electronics devices that may comprise the load 24 (FIG. 1-2) as described above. The thermoelectric generator 10 may be electrically connectable to the load such as via one or more wires 174 as shown in FIG. 4. The thermoelectric generator 10 may be electrically connected to the load with a flexible printed circuit. The wires 174 may be fixed in position by one or more wire constraints 176. The wires 174 may also preferably be arranged in a manner that accommodates the stretching of the inner and outer material layer 162, 164 when the system 111 is worn by a user. The wires 174 may be at least partially encapsulated in the thermally insulating middle layer 166 and may terminate at the thermoelectric generator 10. Electrical wiring may be interconnected to the thermoelectric generator 10, the electronics 172, and/or to other devices by soldering, spot-welding, electrically conductive adhesive, or by other means.

Additional modifications and improvements of the present disclosure may be apparent to those of ordinary skill in the art. Thus, the particular combination of parts described and illustrated herein is intended to represent only certain embodiments of the present disclosure and is not intended to serve as limitations of alternative embodiments or devices within the spirit and scope of the disclosure.

What is claimed is:

1. A power management system for an energy harvesting device, comprising:
a priming circuit being associated with a conditioning and control circuit, the conditioning and control circuit being configured to accumulate energy from a source voltage until an output voltage becomes regulated for a load;
the priming circuit being configured to supplement the source voltage produced by an energy harvesting device during a load period upon the actuation of a power management switch causing the transferring of a priming charge from a low-leakage energy storage element to the conditioning and control circuit; and
the conditioning and control circuit combining the priming charge with the energy accumulating from the source voltage and causing the output voltage for the load to be regulated during the load period following actuation of the power management switch.

2. The power management system of claim 1, wherein the energy harvesting device is a thermoelectric generator.

3. The power management system of claim 1, wherein the priming circuit comprises a transistor switch transferring the priming charge from the low-leakage energy storage element to a temporary storage element over a time period controlled by a timing circuit, the timing circuit being coupled to the transistor switch and actuated by the power management switch.

4. The power management system of claim 3, wherein the transistor switch is a Darlington transistor.

5. The power management system of claim 3, wherein the temporary storage element comprises at least one capacitor.

6. The power management system of claim 3, wherein the timing circuit is a resistor-capacitor (RC) circuit.

7. The power management system of claim 3, wherein the temporary storage element is charged with a priming charge substantially less than an energy storage capacity of the low-leakage energy storage element.

8. The power management system of claim 1, wherein the conditioning and control circuit includes a boost circuit configured to increase the source voltage for delivery to the load.

9. The power management system of claim 1, wherein the conditioning and control circuit further includes a voltage regulator comprising at least one of the following: a low drop out voltage regulator, a buck circuit.

10. The power management system of claim 1, wherein the low-leakage energy storage element comprises a thin film rechargeable battery.

11. The power management system of claim 1, wherein the power management switch is manually actuated.

12. The power management system of claim 1, wherein the power management switch is actuated by a microcontroller.

13. The power management system of claim 1, wherein the power management switch is configured to deactivate the conditioning and control circuit.

14. A power management system for a thermoelectric generator, comprising:
a priming circuit being associated with a conditioning and control circuit, the conditioning and control circuit being configured to accumulate energy from a source voltage until an output voltage becomes regulated for a load;
the priming circuit being configured to supplement the source voltage produced by a thermoelectric generator during a load period upon the actuation of a power management switch, the priming circuit further comprising a low-leakage energy storage element, a temporary storage element, a timing circuit, and a transistor switch having first and second pass terminals and a pass channel therebetween which is normally open, the power management switch coupling to the gating terminals of the transistor switch through the timing circuit, the low-leakage energy storage element connecting to the first pass terminal, the temporary storage element connecting to the second pass terminal, a charging current ceasing according to the timing circuit following the actuation of the power management switch, whereupon the temporary storage element is charged with a priming charge substantially less than an energy storage capacity of the low-leakage energy storage element, the temporary storage element being connected to the conditioning and control circuit; and
the conditioning and control circuit combining the priming charge with the energy accumulating from the source voltage and causing the output voltage for the load to be regulated during the load period following actuation of the power management switch.

15. A method of increasing the power available to a load in an energy harvesting system, comprising the steps of:
delivering a source voltage from an energy harvesting device to a conditioning and control circuit and to a load;
accumulating, within the conditioning and control circuit, energy from the source voltage until an output voltage is regulated for the load;
detecting an amount of power available to the load during a load period being less than a predetermined threshold;
actuating a power management switch causing the transferring of a priming charge from a low-leakage energy storage element to a temporary storage element and presenting the priming charge to the conditioning and control circuit;
combining the priming charge with the energy accumulating from the source voltage, thereby regulating the output voltage for the load during the load period;
maintaining a regulated output voltage during subsequent load periods by harvesting power from the energy harvesting device; and
wherein the priming charge is substantially less than a capacity of the low-leakage storage element.

16. The method of claim 15, further comprising the step of:
repeating the actuation of the power management switch if the power available to the load during the load period is less than a predetermined threshold.

17. The method of claim 15, wherein the step of delivering the source voltage from the energy harvesting device comprises:
delivering the source voltage from a thermoelectric generator.

18. The method of claim 15, further comprising the step of:
increasing the source voltage for delivery to the load using a boost circuit of the conditioning and control circuit.

19. The method of claim 15, wherein the conditioning and control circuit further comprises a voltage regulator comprising at least one of the following: a low drop out voltage regulator, a buck circuit.

20. The method of claim 15, wherein the low-leakage energy storage element comprises a thin film rechargeable battery.

21. The method of claim 15, wherein the temporary storage element comprises at least one capacitor.

22. The method of claim 15, further comprising the step of:
manually actuating the power management switch.

23. The method of claim 15, further comprising the step of:
actuating the power management switch using a microcontroller.

24. The method of claim 15, further comprising the step of:
deactivating the conditioning and control circuit using the power management switch.
